(19) United States
(12) Patent Application Publication
(10) Pub. No.: US 2025/0258231 A1
(43) Pub. Date: Aug. 14, 2025

(54) BATTERY CONTROL DEVICE, BATTERY PACK AND CONTROL METHOD OF BATTERY PACK

(71) Applicant: Samsung SDI Co., Ltd., Yongin-si (KR)

(72) Inventor: Byeongseon Min, Yongin-si (KR)

(73) Assignee: Samsung SDI Co., Ltd., Yongin-si (KR)

(21) Appl. No.: 18/805,803

(22) Filed: Aug. 15, 2024

(30) Foreign Application Priority Data
Feb. 14, 2024 (KR) 10-2024-0021248

(51) Int. Cl. G01R 31/327; H02J 7/00

(52) U.S. Cl. CPC G01R 31/3278; H02J 7/00032; H02J 7/0013; H02J 7/0029; H02J 7/00712; H02J 2207/20

(57) ABSTRACT

The present disclosure relates to a battery control device, a battery pack, and a control method of the battery pack. A battery control device according to an exemplary embodiment for achieving the above-mentioned technical object is a battery control device of a battery pack comprising a plurality of pack terminals and a battery module connected between the plurality of pack terminals, and may include a first switch connected between a first pack terminal of the plurality of pack terminals and the battery module, a first DC/DC converter configured to reduce a voltage which is supplied from the battery module, and supply the reduced voltage to the plurality of pack terminals, and a control device configured to open the first switch, control the first DC/DC converter to reduce the voltages of the plurality of pack terminals, and diagnose a failure of the first switch by comparing voltage values measured at both of respective ends of the first switch, when in a switch diagnosis mode.

### CROSS-REFERENCE TO RELATED APPLICATIONS

This present application claims priority to and the benefit under 35 U.S.C. § 119(a)-(d) of Korean Patent Application No. 10-2024-0021248, filed on Feb. 14, 2024, in the Korean Intellectual Property Office, the entire disclosure of which is incorporated herein by reference.

### FIELD

The present disclosure relates to a battery control device, a battery pack, and a control method of the battery pack.

### BACKGROUND

Secondary batteries are batteries which can be charged and discharged unlike primary batteries which cannot be charged. Low-capacity secondary batteries are used in portable small-sized electronic devices such as smart phones, feature phones, laptops, digital cameras, and camcorders, and high-capacity secondary batteries are extensively used as power sources for driving motors of hybrid vehicles, electric vehicles, and so on and as electricity storage devices. Such a secondary battery includes an electrode assembly consisting of a cathode and an anode, a case that accommodates the electrode assembly, and electrode terminals that are connected to the electrode assembly, among other components.

The above information disclosed in this section of Description of the Related Art of BACKGROUND OF THE INVENTION is only for enhancement of understanding of the background of the present invention, and therefore it may contain information that does not form the related art.

### SUMMARY

Aspects of the technology described herein provide a battery control device, a battery pack, and a control method of the battery pack capable of diagnosing the state of a power switch even when control on a load-side DC link voltage is impossible.

However, technical objects which the technology described herein attempts to achieve are not limited to the above-mentioned object, and unmentioned objects may be clearly understood from the following description by those skilled in the art.

A battery control device according to an exemplary embodiment for achieving the above-mentioned technical object is a battery control device of a battery pack comprising a plurality of pack terminals and a battery module connected between the plurality of pack terminals, and may include a first switch connected between a first pack terminal of the plurality of pack terminals and the battery module, a first DC/DC converter configured to reduce a voltage which is supplied from the battery module, and supply the reduced voltage to the plurality of pack terminals, and a control device configured to open the first switch, control the first DC/DC converter to reduce the voltages of the plurality of pack terminals, and diagnose a failure of the first switch by comparing voltage values measured at both of respective ends of the first switch, when in a switch diagnosis mode.

The control device may be further configured to communicate with a load connected to the plurality of pack terminals.

The control device may be further configured to operate the first DC/DC converter to reduce the voltages of the plurality of pack terminals when in the switch diagnosis mode, if it is determined through the communicating that DC link voltage control of the load is impossible. The control device may be further configured to deactivate the first DC/DC converter when in the switch diagnosis mode, if it is determined that DC link voltage control of the load is normal.

The control device may be further configured to communicate with a load connected to the plurality of pack terminals, notify the load of entry into the switch diagnosis mode, and obtain authorization from the load for control of the DC link voltage of the load.

The battery module may include first and second cell stacks.

The first DC/DC converter may include first and second terminals that are each connected to a respective end of the first cell stack, and third and fourth terminals that are each connected to a respective one of the plurality of pack terminals. The first DC/DC converter may be further configured to reduce a voltage, which is supplied from the first cell stack, in response to a control signal that is received from the control device, and output the reduced voltage to the plurality of pack terminals.

The battery control device may further include a second switch connected between the first and second cell stacks, and a second DC/DC converter that includes first and second terminals that are each connected to a respective end of the second cell stack, and third and fourth terminals that are each connected to a respective one of the plurality of pack terminals. The second DC/DC converter may be a bidirectional converter.

The control device may be further configured to open the second switch, if it is determined that the first switch is in a failure state. The control device may be further configured to control the second DC/DC converter to boost a voltage that is supplied from the second cell stack and supply the boosted voltage to the plurality of pack terminals during discharging, if it is determined that the first switch is in a failure state. The control device may be further configured to control the second DC/DC converter to reduce a voltage that is input through the plurality of pack terminals and charge the second cell stack during charging, if it is determined that the first switch is in a failure state.

The battery control device may further include a third switch connected between a second pack terminal of the plurality of pack terminals and the battery module. The control device may be further configured to open the third switch, when in the switch diagnosis mode. The control device may be further configured to diagnose a failure of the third switch by comparing voltage values measured at respective ends of the third switch, when in the switch diagnosis mode.

The first DC/DC converter may be a bidirectional converter.

The control device may be further configured to open the second switch, if it is determined that the third switch is in a failure state. The control device may be further configured to control the first DC/DC converter to boost a voltage that is supplied from the first cell stack and supply the boosted voltage supplied from the first cell stack to the plurality of pack terminals during discharging, if it is determined that the third switch is in a failure state. The control device may be further configured to control the first DC/DC converter to reduce a voltage that is input through the plurality of pack terminals and charge the first cell stack during charging, if it is determined that the third switch is in a failure state.

The first and second DC/DC converters may be resonant converters that generate vibration energy when operating. The first DC/DC converter may be disposed so as to be in contact with the third switch or may be disposed together with the third switch on a same substrate so as to be in close proximity to the third switch within a predetermined distance. The second DC/DC converter may be disposed so as to be in contact with the first switch, or may be disposed together with the first switch on a same substrate so as to be in close proximity to the first switch within a predetermined distance.

The battery control device may further include a measurement device.

The measurement device may include a first capacitor connected between a first terminal of the first switch and a ground, a second capacitor connected between a second terminal of the first switch and the ground, a first voltage measurement device configured to measure respective voltages of respective ends of the first capacitor and outputs a voltage signal corresponding to a voltage value of the first terminal of the first switch to the control device, and a second voltage measurement device configured to measure respective voltages of respective ends of the second capacitor and outputs a voltage signal corresponding to a voltage value of the second terminal of the first switch to the control device.

The measurement device may further include a third capacitor connected between a first terminal of the third switch and the ground, a fourth capacitor connected between a second terminal of the third switch and the ground, a third voltage measurement device configured to measure the respective voltages of respective ends of the third capacitor and outputs a voltage signal corresponding to a voltage value of a first terminal of the third switch to the control device, and a fourth voltage measurement device configured to measure respective voltages of both ends of the fourth capacitor and outputs a voltage signal corresponding a voltage value of a second terminal of the third switch to the control device.

A battery pack according to an exemplary embodiment may include a plurality of pack terminals, a battery module connected between the plurality of pack terminals, and the battery control device including at least one of the above-mentioned features.

A control method of a battery pack according to an exemplary embodiment may include entering a switch diagnosis mode, opening a first switch connected between a first pack terminal of a plurality of pack terminals of the battery pack and a battery module, controlling a first DC/DC converter to reduce a voltage that is supplied from the battery module and supply the reduced voltage to the plurality of pack terminals, obtaining voltage values measured at respective ends of the first switch, and diagnosing a failure of the first switch by comparing the measured voltage values.

The control method may further include communicating with the load to determine whether DC link voltage control of the load is impossible.

The controlling the first DC/DC converter may include operating the first DC/DC converter to reduce voltages of the plurality of pack terminals if the DC link voltage control of the load is impossible, and deactivating the first DC/DC converter if the DC link voltage control of the load is normal.

The control method may further include notifying the load of entry into a diagnosis mode and obtaining control authority for the DC link voltage of the load when in the switch diagnosis mode.

In the control method, the battery module may include first and second cell stacks.

The control method may further include opening a second switch connected between the first and second cell stacks, if it is determined that the first switch is in a failure state, controlling a second DC/DC converter, connected between the second cell stack and the plurality of pack terminals, to boost a voltage that is supplied from the second cell stack and supply the boosted voltage to the plurality of pack terminals, when entering a discharge mode, and controlling the second DC/DC converter to reduce a voltage that is input through the plurality of pack terminals and charge the second cell stack, when entering a charge mode.

In the control method, the second DC/DC converter may be a bidirectional converter that includes first and second terminals which are connected to respective ends of the second cell stack, respectively, and third and fourth terminals that are connected to respective ones of the plurality of pack terminals, respectively.

The control method may further include opening a third switch connected between a second pack terminal of the plurality of pack terminals and the battery module, obtaining voltage values measured at respective ends of the third switch, and diagnosing a failure of the third switch by comparing the voltage values measured at the respective ends of the third switch.

In the control method, the first DC/DC converter may be a bidirectional converter that includes first and second terminals which are connected to respective ends of the first cell stack, respectively, and third and fourth terminals that are connected to the plurality of pack terminals, respectively.

The control method may further include controlling the first DC/DC converter to boost a voltage that is supplied from the first cell stack and supply the boosted voltage to the plurality of pack terminals, when entering a discharge mode, and controlling the first DC/DC converter to reduce a voltage that is input through the plurality of pack terminals and charge the first cell stack, when entering a charge mode.

According to aspects of the technology described herein, it is possible to diagnose the state of a power switch even when control on a load-side DC link voltage is impossible. Also, it is possible to continue charging and discharging while ensuring the safety of a battery pack even when any one power switch has been welded.

However, effects which can be obtained through the technology described herein are not limited to the above-mentioned effects, and unmentioned other technical effects may be clearly understood from the following description by those skilled in the art.

### BRIEF DESCRIPTION OF THE DRAWINGS

The drawings accompanying this specification illustrate preferred exemplary embodiments of the technology described herein, and serve to provide further understanding of the technical ideas of the technology described herein, together with the following description. Therefore, the technology described herein should not be construed as being limited only to what is described in the drawings.

FIG. 1 is a structural diagram schematically illustrating a battery pack according to an exemplary embodiment.

FIG. 2 schematically illustrates the circuit configuration of a measurement device of a battery pack according to an exemplary embodiment.

FIG. 3 schematically illustrates a control method of a battery pack according to an exemplary embodiment.

FIG. 4 schematically illustrates a switch failure diagnosis method of a battery pack according to an exemplary embodiment.

### DETAILED DESCRIPTION

Hereinafter, preferred exemplary embodiments of the present invention will be described in detail with reference to the accompanying drawings. Prior to the description, it should be understood that terms and words used in the specification and the claims should not be construed as being limited to general and dictionary meanings, but should be interpreted as the meanings and concepts corresponding to the technical ideas of the present invention in view of the principle that the inventor can properly define the concepts of terms in order to describe their invention in the best way. Accordingly, it should be understood that since the exemplary embodiments described in this specification and the configurations shown in the drawings are just the most preferred exemplary embodiments of the present invention and do not represent all of the technical ideas of the present invention, there may be various equivalents and modifications that replace them at the time of filing the application. Further, as used in this specification, the terms “comprise or include” and/or “comprising or including” are intended to specify the presence of the mentioned shapes, numbers, steps, operations, members, elements, and/or groups thereof, and are not intended to exclude the presence or addition of one or more other shapes, numbers, operations, members, elements, and/or groups thereof. Also, as exemplary embodiments of the present invention is described, the word “may” or “may be” is intended to include “one or more exemplary embodiments of the present invention”.

Also, for ease understanding of the present disclosure, the accompanying drawings are not drawn to real scale, but the dimensions of some components may be exaggerated. Further, identical components in exemplary embodiments that differ from one another may be given the same reference numerals.

When two comparison objects are referred to as being “identical”, it means that they are “substantially identical”. Accordingly, being substantially identical is intended to include a case where they have a deviation that is considered as being low in the art, for example, a deviation of 5% or less. Also, when a parameter is referred to as being uniform in a region, it may mean that the parameter is uniform from an average perspective.

Although the terms “first”, “second”, and the like are used to describe various constituent elements, it is apparent that these constituent elements are not limited by these terms. These terms are only used to distinguish one constituent element from other constituent elements, and it is apparent that a first constituent element may be a second constituent element unless particularly otherwise defined.

Throughout the specification, each constituent element may be written in a singular form or a plural form unless particularly otherwise defined.

When an arbitrary component is referred to as being disposed “on (or below)” a constituent element or “above (or beneath) a constituent element,” this may mean not only that the arbitrary component is disposed in contact with the upper surface (or lower surface) of the constituent element but also that other components may be interposed between the constituent element and the arbitrary component disposed above (or beneath) the constituent element.

Also, it should be understood that when a constituent element is referred to as being “coupled”, “combined”, or “connected” to another constituent element, the constituent elements may be directly coupled or connected to each other, or other constituent elements may be “interposed” between the individual constituent elements, and the individual constituent elements may be “coupled”, “combined”, or “connected through other constituent elements. Also, when a part is referred to as being electrically coupled to another part, this includes not only that they are directly coupled but also that they are coupled with other intervening elements therebetween.

Throughout the specification, “A and/or B” means “A, B, or A and B” unless particularly otherwise defined. In other words, the term “and/or” includes all combinations or any combinations of a plurality of listed items. The term “C to D” means being equal to or larger than C and equal to or smaller than D unless particularly otherwise defined.

As described herein, secondary batteries are batteries that can be charged and discharged. Secondary batteries typically comprise an electrode assembly consisting of a cathode and an anode, a case that accommodates the electrode assembly, and electrode terminals that are connected to the electrode assembly. The secondary battery is combined with a charge and discharge circuit to form a battery pack, and charging by an external power source and discharging to an external load are performed through pack terminals included in the battery pack. Between the pack terminals of the battery pack and the battery, a power switch (for example, a relay) for controlling power transfer is connected. In the power switch, a failure such as welding may occur. A failure of the power switch reduces the performance and safety of the battery pack, so it is necessary to continuously diagnose whether the power switch has failed.

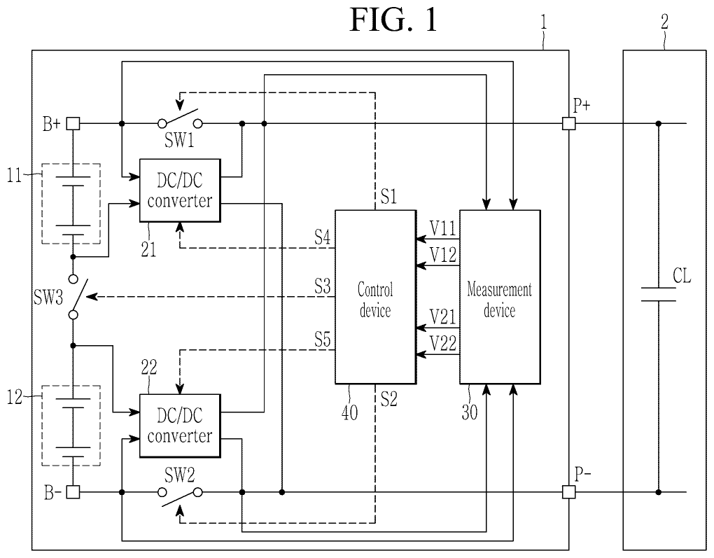

FIG. 1 is a structural diagram schematically illustrating a battery pack according to an exemplary embodiment.

Referring to FIG. 1, a battery pack 1 according to an exemplary embodiment may include a plurality of pack terminals P+and P−, a battery module connected between the plurality of pack terminals P+and P−, and a battery control device. The battery control device may include a plurality of switches SW3, SW1, and SW2, a plurality of DC/DC converters 21 and 22, a measurement device 30, and a control device 40.

The battery module may include a plurality of module terminals B+ and B−and a plurality of cell stacks 11 and 12. The plurality of cell stacks 11 and 12 may be electrically connected in series with each other between the plurality of module terminals B+ and B−. Each of the cell stacks 11 and 12 may include a plurality of cells that is electrically connected in series and/or in parallel with one another.

The switch SW3 may be electrically connected between the plurality of cell stacks 11 and 12. The switch SW3 can break an electrical connection between the plurality of cell stacks 11 and 12, or electrically connect the plurality of cell stacks 11 and 12 to each other. The switch SW3 may be controlled to be opened or closed by a control signal S3 that is received from the control device 40 described herein. The switch SW3 may include a switching device such as a relay, a contactor, etc.

The switch SW1 may be electrically connected between the positive module terminal B+ of the battery module and the positive pack terminal P+. The switch SW1 can break an electrical connection between the positive module terminal B+ and the positive pack terminal P+, or electrically connect the positive module terminal B+ and the positive pack terminal P+ to each other. The switch SW1 may be controlled to be opened or closed by a control signal S1 that is received from the control device 40 described herein. The switch SW1 may include a switching device such as a relay, a contactor, etc.

The switch SW2 may be electrically connected between the negative module terminal B− of the battery module and the negative pack terminal P−. The switch SW2 can break an electrical connection between the negative module terminal B− and the negative pack terminal P−, or electrically connect the negative module terminal B− and the negative pack terminal P− to each other. The switch SW2 may be controlled to be opened or closed by a control signal S2 that is received from the control device 40 described herein. The switch SW2 may include a switching device such as a relay, a contactor, etc.

The DC/DC converter 21 may include a first terminal that is electrically connected between the positive module terminal B+ of the battery module and the switch SW1, and a second terminal that is electrically connected between the cell stack 11 and the switch SW3. The DC/DC converter 21 may include a third terminal that is electrically connected between the switch SW1 and the positive pack terminal P+, and a fourth terminal that is electrically connected between the switch SW2 and the negative pack terminal P−. In other words, the DC/DC converter 21 may include the first and second terminals that are electrically connected to both ends of the cell stack 11, respectively, and the third and fourth terminals that are electrically connected to the pack terminals P+ and P−, respectively.

The DC/DC converter 21 may operate as a bidirectional converter. The DC/DC converter 21 may operate in a discharge mode for converting a voltage input through the first and second terminals and outputting it to the third and fourth terminals, and a charge mode for converting a voltage input through the third and fourth terminals and outputting it to the first and second terminals. In the discharge mode, the DC/DC converter 21 may boost a voltage input from the cell stack 11, and supply the boosted voltage to a load 2 through the pack terminals P+and P−. In the charge mode, the DC/DC converter 21 may reduce a charging voltage input from a charger (not shown in the drawings) through the pack terminals P+and P−, and supply the reduced voltage as a charging voltage for the cell stack 11.

The DC/DC converter 21 may operate in a diagnosis mode for diagnosing a failure of the switch SW1. In the diagnosis mode, the DC/DC converter 21 may reduce a voltage input from the cell stack 11 and output the reduced voltage to the pack terminals P+ and P−.

The DC/DC converter 21 may receive a control signal S4 from the control device 40 described herein, and adjust the output voltage in response to the control signal S4.

The DC/DC converter 22 may include a first terminal that is electrically connected between the negative module terminal B− of the battery module and the switch SW2, and a second terminal that is electrically connected between the cell stack 12 and the switch SW3. The DC/DC converter 22 may include a third terminal that is electrically connected between the switch SW1 and the positive pack terminal P+, and a fourth terminal that is electrically connected between the switch SW2 and the negative pack terminal P−. In other words, the DC/DC converter 22 may include the first and second terminals that are electrically connected to both ends of the cell stack 12, respectively, and the third and fourth terminals that are electrically connected to the pack terminals P+ and P−, respectively.

The DC/DC converter 22 may operate as a bidirectional converter. The DC/DC converter 22 may operate in a discharge mode for converting a voltage input through the first and second terminals and outputting it to the third and fourth terminals, and a charge mode for converting a voltage input through the third and fourth terminals and outputting it to the first and second terminals. In the discharge mode, the DC/DC converter 22 may boost a voltage input from the cell stack 12, and supply the boosted voltage to the load 2 through the pack terminals P+ and P−. In the charge mode, the DC/DC converter 22 may reduce a charging voltage input from a charger (not shown in the drawings) through the pack terminals P+ and P−, and supply the reduced voltage as a charging voltage for the cell stack 12.

The DC/DC converter 22 may operate in a diagnosis mode for diagnosing a failure of the switch SW2. In the diagnosis mode, the DC/DC converter 22 may reduce a voltage input from the cell stack 12 and output the reduced voltage to the pack terminals P+ and P−.

The DC/DC converter 22 may receive a control signal S5 from the control device 40 described herein, and adjust the output voltage in response to the control signal S5.

Each of the DC/DC converters 21 and 22 may include a resonant converter including a resonance circuit. For example, the DC/DC converters 21 and 22 may include various resonant converters such as serial resonant converters (SRCs), parallel resonant converters (PRCs), LLC resonant converters, zero voltage switching (ZVS) resonant converters, zero current switching (ZCS) resonant converters, etc.

The DC/DC converter 21 may be disposed in contact with the switch SW2 inside the housing of the battery pack 1. The DC/DC converter 21 may be positioned together with the switch SW2 on the same substrate, and be disposed at such a position that vibration energy due to the resonance of the DC/DC converter 21 is sufficiently transferred to the switch SW2, i.e., at a position in close proximity to the switch SW2 within a predetermined distance. Accordingly, when the DC/DC converter 21 operates, vibration energy due to the resonance of the DC/DC converter 21 can be transferred to the switch SW2 to vibrate the switch SW2. This vibration energy can be used as energy for resolving welding of the switch SW2.

The DC/DC converter 22 may be disposed in contact with the switch SW1 inside the housing of the battery pack 1. The DC/DC converter 22 may be positioned together with the switch SW1 on the same substrate, and be disposed at such a position that vibration energy due to the resonance of the DC/DC converter 22 is sufficiently transferred to the switch SW1, i.e., at a position in close proximity to the switch SW1 within a predetermined distance. Accordingly, when the DC/DC converter 22 operates, vibration energy due to the resonance of the DC/DC converter 22 can be transferred to the switch SW1 to vibrate the switch SW1. This vibration energy can be used as energy for resolving welding of the switch SW1.

The measurement device 30 may perform a voltage measurement function for diagnosing failures of the switches SW1 and SW2. The measurement device 30 may measure each of the voltages at both ends of the switch SW1. For example, the measurement device 30 may measure the voltage at a node between the positive module terminal B+ of the battery module and the switch SW1. The measurement device 30 may measure the voltage at a node between the switch SW1 and the positive pack terminal P+. The measurement device 30 may transmit voltage values V11 and V12, measured at both ends of the switch SW1, in a voltage signal form to the control device 40.

The measurement device 30 may measure each of the voltages at both ends of the switch SW2. The measurement device 30 may measure the voltage at a node between the negative module terminal B− of the battery module and the switch SW2. The measurement device 30 may measure the voltage at a node between the switch SW2 and the negative pack terminal P−. The measurement device 30 may transmit voltage values V21 and V22, measured at both ends of the switch SW2, in a voltage signal form to the control device 40.

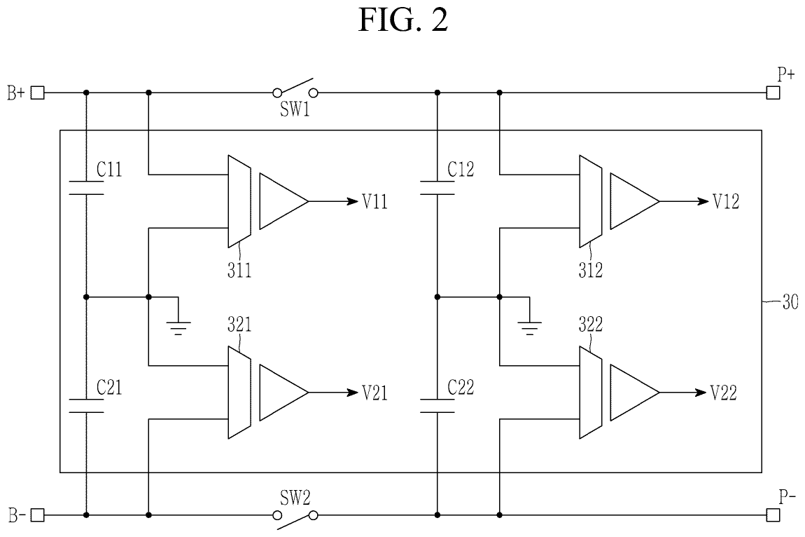

FIG. 2 schematically illustrates the circuit configuration of the measurement device 30 of the battery pack 1 according to an exemplary embodiment.

Referring to FIG. 2, the measurement device 30 according to the exemplary embodiment may include a plurality of capacitors C11, C12, C21, and C22 and a plurality of voltage measurement devices 311, 312, 321, and 322.

The capacitor C11 may be electrically connected between one end of the switch SW1 and a ground. The voltage measurement device 311 may include measurement terminals that are connected to both ends of the capacitor C11, respectively. The voltage measurement device 311 may measure the voltage between both ends of the capacitor C11 (i.e., the voltage between one end of the switch SW1 and the ground) through the measurement terminals, and output the measured voltage value V11 in a voltage signal form. The capacitor C12 may be electrically connected between the other end of the switch SW1 and the ground. The voltage measurement device 312 may include measurement terminals that are connected to both ends of the capacitor C12, respectively. The voltage measurement device 312 may measure the voltage between both ends of the capacitor C12 (i.e., the voltage between the other end of the switch SW1 and the ground) through the measurement terminals, and output the measured voltage value V12 in a voltage signal form.

The capacitor C21 may be electrically connected between one end of the switch SW2 and the ground. The voltage measurement device 321 may include measurement terminals that are connected to both ends of the capacitor C21, respectively. The voltage measurement device 321 may measure the voltage between both ends of the capacitor C21 (i.e., the voltage between one end of the switch SW2 and the ground) through the measurement terminals, and output the measured voltage value V21 in a voltage signal form. The capacitor C22 may be electrically connected between the other end of the switch SW2 and the ground. The voltage measurement device 322 may include measurement terminals that are connected to both ends of the capacitor C22, respectively. The voltage measurement device 322 may measure the voltage between both ends of the capacitor C22 (i.e., the voltage between the other end of the switch SW2 and the ground) through the measurement terminals, and output the measured voltage value V22 in a voltage signal form.

Referring to FIG. 1 again, the control device 40 may diagnose the welded state of each of the switches SW1 and SW2 on the basis of the voltage values V11, V12, V21, and V22 received from the measurement device 30 when entering the diagnosis mode for the switches SW1 and SW2.

The control device 40 may perform overall control operations of the battery pack 1, such as charging/discharging control, switch diagnosis, and the like of the battery pack 1.

As described herein, the control device 40 may operate in the diagnosis mode for performing failure diagnosis of the switches SW1 and SW2.

The control device 40 may output the control signal S1 instructing the switch SW1 to transition to an open state when entering the diagnosis mode for the switch SW1. Thereafter, the control device 40 may receive the voltage values V11 and V12, measured at both ends of the switch SW1, from the measurement device 30. The control device 40 may compare the received voltage values V11 and V12, and determine that the switch SW1 is in a failure state due to welding when the difference between the two voltage values V11 and V12 is equal to or smaller than a predetermined value. On the other hand, the control device 40 may determine that the switch SW1 is in a normal state, when the difference between the two voltage values V11 and V12 exceeds the predetermined value. In the diagnosis mode for the switch SW1, the switch SW3 may remain closed. In the diagnosis mode for the switch SW1, the control device 40 may control the switch SW3 such that it is closed. In the diagnosis mode for the switch SW1, the control device 40 may control the switch SW2 such that it is closed or opened.

The control device 40 may output the control signal S2 instructing the switch SW2 to transition to an open state when entering a diagnosis mode for the switch SW2. Thereafter, the control device 40 may receive the voltage values V21 and V22, measured at both ends of the switch SW2, from the measurement device 30. The control device 40 may compare the received voltage values V21 and V22, and determine that the switch SW2 is in a failure state due to welding when the difference between the two voltage values V21 and V22 is equal to or smaller than a predetermined value. On the other hand, the control device 40 may determine that the switch SW2 is in a normal state, when the difference between the two voltage values V21 and V22 exceeds the predetermined value. In the diagnosis mode for the switch SW2, the control device 40 may control the switch SW3 such that it is closed. In the diagnosis mode for the switch SW2, the control device 40 may control the switch SW1 such that it is closed or opened.

A DC link of the load 2 includes a smoothing capacitor CL. This smoothing capacitor CL requires a significant amount of time to be discharged naturally. Therefore, the load 2 may further include a discharge circuit (not shown in the drawings) for forced discharging of the smoothing capacitor CL, and the discharge circuit is used to discharge the smoothing capacitor CL when necessary. On the other hand, a case where the voltage of the DC link at the load 2 becomes uncontrollable may occur due to causes such as a failure of the discharge circuit. In this case, at least one of the switches SW1 and SW2 is opened such that the voltage of the smoothing capacitor CL slowly decreases even if the power transfer between the battery module and the load 2 is interrupted. In this state, when the control device 40 performs a failure diagnosis of the switches SW1 and SW2 in the above-mentioned manner, a situation may arise where a switch in a normal state is misdiagnosed as being in a welded state.

In order to solve this problem, the control device 40 may operate the DC/DC converter 21 or the DC/DC converter 22 to forcedly reduce the voltage between the pack terminals P+ and P− to a voltage at which a diagnosis is possible, for a failure diagnosis of each of the switches SW1 and SW2.

For a failure diagnosis of the switch SW1, the control device 40 may open the switch SW1 and operate one of the DC/DC converter 21 and the DC/DC converter 22 to reduce the voltage between the pack terminals P+ and P− to a predetermined value or less. Thereafter, the control device 40 may compare the voltage values V11 and V12, measured in this state, to determine whether the switch SW1 has failed.

For a failure diagnosis of the switch SW2, the control device 40 may open the switch SW2 and operate one of the DC/DC converter 21 and the DC/DC converter 22 to reduce the voltage between the pack terminals P+ and P− to a predetermined value or less. Thereafter, the control device 40 may compare the voltage values V21 and V22, measured in this state, to determine whether the switch SW2 has failed.

When the DC/DC converter 21 or the DC/DC converter 22 is used to reduce the voltage between the pack terminals P+ and P−, it may also affect the DC link voltage of the load 2. Therefore, in order to use the DC/DC converters 21 and 22 for a failure diagnosis of each of the switches SW1 and SW2, the control device 40 may get control authority for the DC link voltage of the load 2 by performing communication with the load 2.

The control device 40 may get the control authority for the DC link voltage of the load 2 only when the DC link voltage of the load 2 is in an uncontrollable state. In this case, the control device 40 may transmit a state signal indicative of entering the failure diagnosis mode to the load 2 when entering the failure diagnosis mode for the switches SW1 and SW2. The load 2 receiving the state signal may control the discharge circuit (not shown in the drawings) to reduce the DC link voltage to the predetermined value or less, and check whether the discharge circuit is operating properly. When it is confirmed that the DC link voltage is in an uncontrollable state since the discharge circuit is not operating properly, the load 2 may transmit a notification signal indicating the uncontrollable state of the DC link voltage to the control device 40. The control device 40 may get the control authority for the DC link voltage of the load 2 when receiving the notification signal indicating the uncontrollable state of the DC link voltage from the load 2. In other words, the control device 40 may operate the DC/DC converters 21 and 22 to reduce the voltage between the pack terminals P+ and P− to the predetermined value or less.

When entering the failure diagnosis mode for the switches SW1 and SW2, the control device 40 may get the control authority for the DC link voltage of the load 2 regardless of the control state of the DC link voltage of the load 2. In this case, when entering the failure diagnosis mode for the switches SW1 and SW2, the control device 40 may transmit a state signal indicative of entering the failure diagnosis mode to the load 2 and get the control authority for the DC link voltage of the load 2. Thereafter, the control device 40 may operate the DC/DC converters 21 and 22 to reduce the voltage between the pack terminals P+ and P− to a predetermined value or less. The load 2 notified of the entry into the failure diagnosis mode by the control device 40 may recognize that the DC link voltage will be reduced by the battery pack 1, and prepare for it.

When it is determined by the above-mentioned failure diagnosis operation that any one of the switches SW1 and SW2 is in a welded state, the control device 40 may notify a higher-level controller (for example, the vehicle controller of the vehicle equipped with the battery pack 1) of the switch failure. In some embodiments, the control device 40 may output the control signal S3 to open the switch SW3. Accordingly, the plurality of cell stacks 11 and 12 may be electrically separated from each other. Further, in order to maintain charging and discharging of the battery pack 1 while ensuring the safety of the battery pack 1, the control device 40 may control the DC/DC converters 21 and 22 such that charging and discharging are performed only by any one of the two cell stacks 11 and 12.

If the switch SW1 fails, the control device 40 may stop using the cell stack 11 and perform charging and discharging only on the cell stack 12. For example, during discharging of the battery pack 1, the control device 40 may control the DC/DC converters 21 and 22 such that a voltage necessary for the load (2) side is supplied to only the cell stack 12. In other words, the DC/DC converter 22 may boost the voltage supplied from the cell stack 12 and supply it to the pack terminals P+ and P−, and the DC/DC converter 21 may be inactivated. Also, for example, during charging of the battery pack 1, the control device 40 may control the DC/DC converters 21 and 22 such that only the cell stack 12 is charged by the voltage supplied from the charger (not shown in the drawings). In other words, the DC/DC converter 22 may reduce the voltage supplied from the charger (not shown in the drawings) and supply the reduced voltage as a charging voltage to the cell stack 12, and the DC/DC converter 21 may be inactivated. At this time, vibration energy which is generated by the operation of the DC/DC converter 22 may be transferred to the switch SW1 and be used as energy for resolving welding of the switch SW1.

If the switch SW2 fails, the control device 40 may stop using the cell stack 12 and perform charging and discharging only on the cell stack 11. For example, during discharging of the battery pack 1, the control device 40 may control the DC/DC converters 21 and 22 such that a voltage necessary for the load (2) side is supplied to only the cell stack 11. In other words, the DC/DC converter 21 may boost the voltage supplied from the cell stack 11 and supply it to the pack terminals P+ and P−, and the DC/DC converter 22 may be inactivated. Also, for example, during charging of the battery pack 1, the control device 40 may control the DC/DC converters 21 and 22 such that only the cell stack 11 is charged by the voltage supplied from the charger (not shown in the drawings). In other words, the DC/DC converter 21 may reduce the voltage supplied from the charger (not shown in the drawings) and supply the reduced voltage as a charging voltage to the cell stack 11, and the DC/DC converter 22 may be inactivated. At this time, vibration energy which is generated by the operation of the DC/DC converter 21 may be transferred to the switch SW2 and be used as energy for resolving welding of the switch SW2.

The control device 40 may include at least one processor. A processor may refer to a data processing device having physically structured circuits for performing functions expressed by codes or instructions included in a program, such as a microprocessor, a central processing unit (CPU), a processor core, a multiprocessor, an application-specific integrated circuit (ASIC), a field programmable gate array (FPGA), etc.

The control device 40 may be configured as a part of a battery management system (BMS) of the battery pack 1.

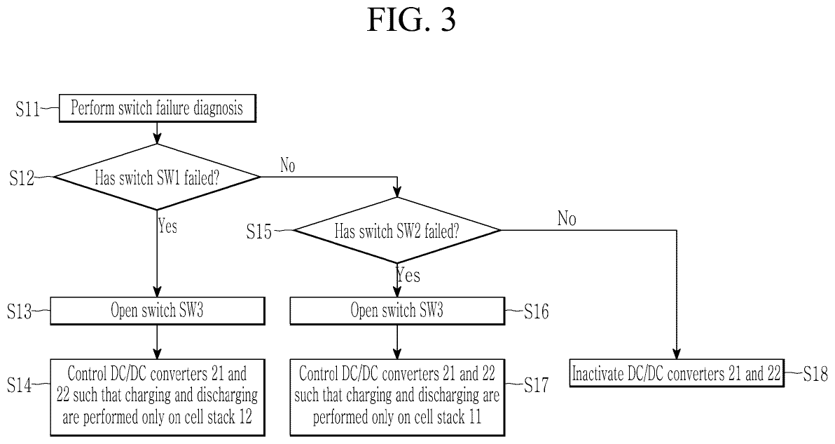

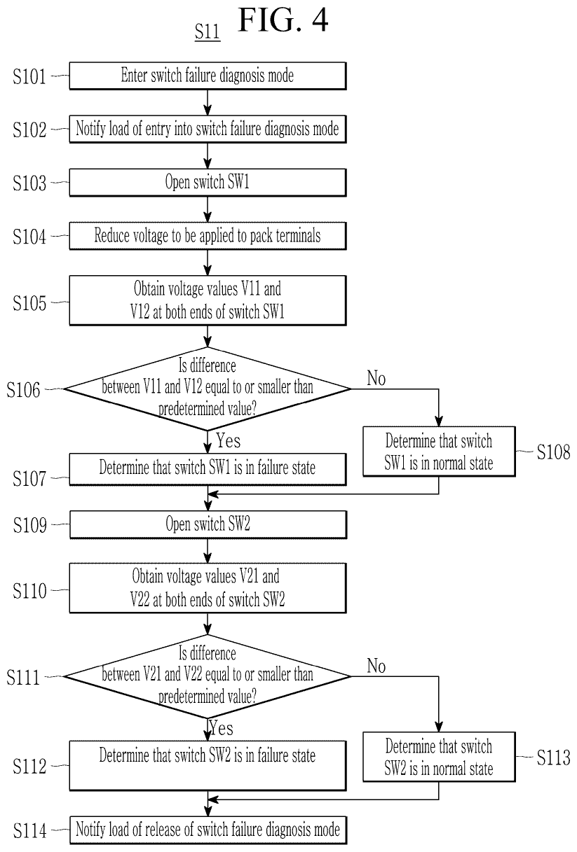

Hereinafter, a control method of the battery pack 1 according to an exemplary embodiment will be described with reference to FIGS. 3 and 4.

FIG. 3 schematically illustrates a control method of the battery pack 1 according to an exemplary embodiment. FIG. 4 schematically illustrates a switch failure diagnosis method of the battery pack 1 according to an exemplary embodiment. The methods of FIGS. 3 and 4 may be performed by the control device 40 described with reference to FIGS. 1 and 2.

Referring to FIG. 3, the control device 40 may perform a failure diagnosis of the switches SW1 and SW2 (S11). The failure diagnosis method of the switches SW1 and SW2 will be described in detail with reference to FIG. 4.

Referring to FIG. 4, the control device 40 may enter the switch failure diagnosis mode (S101), and notify the load 2 of the entry into the switch failure diagnosis mode (S102), and get the control authority for the DC link voltage of the load 2. In some embodiments, only when the DC link voltage of the load 2 is in an uncontrollable state, the control device 40 may get the control authority for the DC link voltage of the load 2. In some embodiments, when entering the failure diagnosis mode for the switches SW1 and SW2, the control device 40 may get the control authority for the DC link voltage of the load 2 regardless of the control state of the DC link voltage of the load 2.

For a failure diagnosis of the switch SW1, the control device 40 may open the switch SW1 (S103). At this time, the control device 40 may control the switch SW3 to be closed, and control the switch SW2 to be closed or opened

Then, the control device 40 may operate one of the DC/DC converter 21 and the DC/DC converter 22 to reduce the voltage between the pack terminals P+ and P− to the predetermined value or less (S104), and obtain each of the voltage values V11 and V12 at both ends of the switch SW1 through the measurement device 30 (S105).

When obtaining the voltage values V11 and V12 in STEP S105, the control device 40 may determine whether the difference between the two voltage values V11 and V12 is equal to or smaller than the predetermined value, or not (S106). When the difference between the two voltage values V11 and V12 is equal to or smaller than the predetermined value, the control device 40 may determine that the switch SW1 is in a failure state (S107). In contrast, when the difference between the two voltage values V11 and V12 is larger than the predetermined value, the control device 40 may determine that the switch SW1 is in the normal state (S108).

Thereafter, the control device 40 may open the switch SW2 for a failure diagnosis of the switch SW2 (S109). At this time, the control device 40 may control the switch SW3 such that it is closed, and control the switch SW1 such that it is closed or opened.

Then, the control device 40 may obtain each of the voltage values V21 and V22 at both ends of the switch SW2 through the measurement device 30 (S110). At this time, the voltage between the pack terminals P+ and P− is the voltage already reduced in STEP S104 described above.

When obtaining the voltage values V21 and V22 in STEP S110, the control device 40 may determine whether the difference between the two voltage values V21 and V22 is equal to or smaller than the predetermined value, or not (S111). When the difference between the two voltage values V21 and V22 is equal to or smaller than the predetermined value, the control device 40 may determine that the switch SW2 is in a failure state (S112). In contrast, when the difference between the two voltage values V21 and V22 are larger than the predetermined value, the control device 40 may determine that the switch SW2 is in the normal state (S113).

When the failure diagnosis of the switches SW1 and SW2 is completed through the above-mentioned process, the control device 40 may transmit a state signal notifying the release of the switch failure diagnosis mode to the load 2 (S114). Accordingly, the control authority for the DC link voltage of the load 2 may be returned to the load 2.

Referring to FIG. 3 again, when it is determined as the result of the failure diagnosis of STEP S11 that the switch SW1 has failed (S12), the control device 40 may open the switch SW3 (S13). Accordingly, the plurality of cell stacks 11 and 12 may be electrically separated from each other.

Also, the control device 40 may stop using the cell stack 11, and control the DC/DC converters 21 and 22 such that charging and discharging are performed only on the cell stack 12 (S14).

In STEP S14, during discharging of the battery pack 1, the control device 40 may control the DC/DC converters 21 and 22 such that a voltage necessary for the load (2) side is supplied to only the cell stack 12. Also, during charging of the battery pack 1, the control device 40 may control the DC/DC converters 21 and 22 such that only the cell stack 12 is charged by the voltage supplied from the charger.

When it is determined as the result of the failure diagnosis of STEP S11 that the switch SW2 has failed (S15), the control device 40 may open the switch SW3 (S16). Accordingly, the plurality of cell stacks 11 and 12 may be electrically separated from each other.

Also, the control device 40 may stop using the cell stack 12, and control the DC/DC converters 21 and 22 such that charging and discharging are performed only on the cell stack 11 (S17).

In STEP S17, during discharging of the battery pack 1, the control device 40 may control the DC/DC converters 21 and 22 such that a voltage necessary for the load (2) side is supplied to only the cell stack 11. Also, during charging of the battery pack 1, the control device 40 may control the DC/DC converters 21 and 22 such that only the cell stack 11 is charged by the voltage supplied from the charger.

When it is determined as the result of the failure diagnosis of STEP S11 that both of the switches SW1 and SW2 are in the normal state, the control device 40 may inactivate the DC/DC converters 21 and 22 such that charging and discharging are performed by the switches SW1 and SW2 (S18).

While the present invention has been described above on the basis of some exemplary embodiments and the drawings, it is to be understood that the present invention is not limited thereto and various changes and modifications can be made within the technical ideas of the present invention and the scope of the claims to be described below by those skilled in the art to which the present invention pertain.

### Description of Symbols

1: Battery pack
2: Load
11, 12: Cell stack
21, 22: DC/DC converter
30: Measurement device
40: Control device
311, 312, 313, 314: Voltage measurement device
P+: Positive pack terminal
P−: Negative pack terminal
B+: Positive module terminal
B−: Negative module terminal
SW1, SW2, SW3: Switch
C11, C12, C13, C14: Capacitor
CL: Smoothing capacitor
S1, S2, S3, S4, S5: Control signal

What is claimed is:

1. A battery control device of a battery pack comprising a plurality of pack terminals and a battery module connected between the plurality of pack terminals, the battery control device comprising:
a first switch connected between a first pack terminal of the plurality of pack terminals and the battery module;
a first DC/DC converter configured to reduce a voltage which is supplied from the battery module, and supply the reduced voltage to the plurality of pack terminals; and
a control device configured to:
open the first switch;
control the first DC/DC converter to reduce the voltages of the plurality of pack terminals; and
diagnose a failure of the first switch by comparing voltage values measured at both of respective ends of the first switch when in a switch diagnosis mode.

2. The battery control device as claimed claim 1, wherein the control device is further configured to:
communicate with a load connected to the plurality of pack terminals;
operate the first DC/DC converter to reduce the voltages of the plurality of pack terminals when in the switch diagnosis mode, if it is determined through the communicating that DC link voltage control of the load is impossible; and
deactivate the first DC/DC converter when in the switch diagnosis mode, if it is determined that DC link voltage control of the load is normal.

3. The battery control device as claimed in claim 1, wherein the control device is configured to:
communicate with a load connected to the plurality of pack terminals;
notify the load of entry into the switch diagnosis mode; and
obtain authorization from the load for control of the DC link voltage of the load.

4. The battery control device as claimed in claim 1, wherein:
the battery module includes first and second cell stacks, and
the first DC/DC converter includes first and second terminals that are each connected to a respective end of the first cell stack, and third and fourth terminals that are each connected to a respective one of the plurality of pack terminals, and
the first DC/DC converter is further configured to reduce a voltage, which is supplied from the first cell stack, in response to a control signal that is received from the control device, and output the reduced voltage to the plurality of pack terminals.

5. The battery control device as claimed in claim 4, further comprising:
a second switch connected between the first and second cell stacks; and
a second DC/DC converter that includes first and second terminals that are each connected to a respective end of the second cell stack, and third and fourth terminals that are each connected to a respective one of the plurality of pack terminals,
wherein the second DC/DC converter is a bidirectional converter,
wherein the control device is further configured to open the second switch, if it is determined that the first switch is in a failure state, and
wherein the control device is further configured to control the second DC/DC converter to boost a voltage that is supplied from the second cell stack and supply the boosted voltage to the plurality of pack terminals during discharging, and control the second DC/DC converter to reduce a voltage that is input through the plurality of pack terminals and charge the second cell stack during charging, if it is determined that the first switch is in a failure state.

6. The battery control device as claimed in claim 5, further comprising a third switch connected between a second pack terminal of the plurality of pack terminals and the battery module,
wherein the control device is further configured to open the third switch, and diagnose a failure of the third switch by comparing voltage values measured at respective ends of the third switch, when in the switch diagnosis mode.

7. The battery control device as claimed in claim 6, wherein:
the first DC/DC converter is a bidirectional converter,
the control device is further configured to open the second switch, if it is determined that the third switch is in a failure state, and
the control device is further configured to control the first DC/DC converter to boost a voltage that is supplied from the first cell stack and supply the boosted voltage supplied from the first cell stack to the plurality of pack terminals during discharging, and control the first DC/DC converter to reduce a voltage that is input through the plurality of pack terminals and charge the first cell stack during charging, if it is determined that the third switch is in a failure state.

8. The battery control device as claimed in claim 6, wherein:
the first and second DC/DC converters are resonant converters that generate vibration energy when operating,
the first DC/DC converter is disposed so as to be in contact with the third switch or is disposed together with the third switch on a same substrate so as to be in close proximity to the third switch within a predetermined distance, and
the second DC/DC converter is disposed so as to be in contact with the first switch, or is disposed together with the first switch on a same substrate so as to be in close proximity to the first switch within a predetermined distance.

9. The battery control device as claimed in claim 6, further comprising a measurement device,
wherein the measurement device includes:
a first capacitor connected between a first terminal of the first switch and a ground;
a second capacitor connected between a second terminal of the first switch and the ground;
a first voltage measurement device configured to measure respective voltages of respective ends of the first capacitor and output a voltage signal corresponding to a voltage value of the first terminal of the first switch to the control device;
a second voltage measurement device configured to measure respective voltages of respective ends of the second capacitor and output a voltage signal corresponding to a voltage value of the second terminal of the first switch to the control device;
a third capacitor connected between a first terminal of the third switch and the ground;
a fourth capacitor connected between a second terminal of the third switch and the ground;
a third voltage measurement device configured to measure respective voltages of respective ends of the third capacitor and output a voltage signal corresponding to a voltage value of a first terminal of the third switch to the control device; and
a fourth voltage measurement device configured to measure respective voltages of respective ends of the fourth capacitor and output a voltage signal corresponding a voltage value of a second terminal of the third switch to the control device.

10. A battery pack comprising:
the battery control device as claimed in claim 1;
the plurality of pack terminals; and
the battery module connected between the plurality of pack terminals.

11. A control method of a battery pack, the control method comprising:
entering a switch diagnosis mode;
opening a first switch connected between a first pack terminal of a plurality of pack terminals of the battery pack and a battery module;
controlling a first DC/DC converter to reduce a voltage that is supplied from the battery module and supply the reduced voltage to the plurality of pack terminals;
obtaining voltage values measured at respective both ends of the first switch; and
diagnosing a failure of the first switch by comparing the measured voltage values.

12. The control method as claimed in claim 11, further comprising:
communicating with a load to determine whether DC link voltage control of the load is impossible,
wherein the controlling the first DC/DC converter includes:
operating the first DC/DC converter to reduce voltages of the plurality of pack terminals if the DC link voltage control of the load is impossible; and
deactivating the first DC/DC converter if the DC link voltage control of the load is normal.

13. The control method as claimed in claim 11, further comprising:
notifying a load of entry into a diagnosis mode and obtaining control authority for the DC link voltage of the load when in the switch diagnosis mode.

14. The control method as claimed in claim 11, wherein:
the battery module includes first and second cell stacks, and
the control method further comprises:
opening a second switch connected between the first and second cell stacks, if it is determined that the first switch is in a failure state;
controlling a second DC/DC converter, connected between the second cell stack and the plurality of pack terminals, to boost a voltage that is supplied from the second cell stack and supply the boosted voltage to the plurality of pack terminals, when entering a discharge mode; and
controlling the second DC/DC converter to reduce a voltage that is input through the plurality of pack terminals and charge the second cell stack, when entering a charge mode, and
the second DC/DC converter is a bidirectional converter that includes first and second terminals which are each connected to a respective end of the second cell stack, and third and fourth terminals that are each connected to a respective one of the plurality of pack terminals, respectively.

15. The control method as claimed in claim 14, further comprising:
opening a third switch connected between a second pack terminal of the plurality of pack terminals and the battery module;
obtaining voltage values measured at respective ends of the third switch; and
diagnosing a failure of the third switch by comparing the voltage values measured at the respective ends of the third switch.

16. The control method as claimed in claim 15, wherein:
the first DC/DC converter is a bidirectional converter that includes first and second terminals which are connected to a respective end of the first cell stack, respectively, and third and fourth terminals that are connected to a respective one of the plurality of pack terminals, respectively,
the control method further comprises:
controlling the first DC/DC converter to boost a voltage that is supplied from the first cell stack and supply the boosted voltage to the plurality of pack terminals, when entering a discharge mode; and
controlling the first DC/DC converter to reduce a voltage that is input through the plurality of pack terminals and charge the first cell stack, when entering a charge mode.
